(19) United States
(12) Patent Application Publication
(10) Pub. No.: US 2007/0105390 A1
(43) Pub. Date: May 10, 2007

(54) Oxygen depleted etching process

(76) Inventor: Travis Byonghyop Oh, San Jose, CA (US)

Correspondence Address: UNITY SEMICONDUCTOR CORPORATION, 250 NORTH WOLFE ROAD, SUNNYVALE, CA, 94085, US

(21) Appl. No.: 11/584,876

(22) Filed: Oct. 20, 2006

Related U.S. Application Data
(60) Provisional application No. 60/736,091, filed on Nov. 9, 2005.

(51) Int. Cl. H01L 21/465

(52) U.S. Cl. 438/710; 438/717

(57) ABSTRACT

A method for oxygen depleted plasma etching and mixed mode plasma etching are disclosed. The method includes using an oxygen free etch plasma or a substantially oxygen free etch plasma at a high temperature to etch a stack including a plurality of layers of thin film materials. The oxygen depleted etching prevents or substantially reduces by-product re-deposition of titanium oxides generated by etching of titanium thin films in the stack. The titanium oxides can serve as a secondary mask layer that can cause defects in devices formed from the stack. Mixed mode plasma etching can include etching the stack with an oxygen free plasma, a substantially oxygen free plasma, and an oxygen containing plasma at different stages of a process.

### FIELD OF THE INVENTION

The present invention relates generally to processing of thin film structures. More specifically, the present invention relates to plasma etching processes for etching thin film structures.

### BACKGROUND OF THE INVENTION

Titanium (Ti), titanium oxide (TiO), and titanium nitride (TiN) thin films have been used as glue layers (also called adhesion layers) and barrier layers in semiconductor and microelectronic applications. Titanium (Ti) and titanium nitride (TiN) can also be used as hard mask layers for various etching steps due to their resilient etch characteristics, particularly at high etch temperatures encountered in dry etching (e.g., plasma etching) processes. Although conventional photoresist materials can be used as a mask layer, high temperature plasma etching processes can exceed a thermal budget of photoresist materials. At processing temperatures that rise above approximately 150° C., photoresist will begin to reticulate. As the processing temperature approaches approximately 180° C., photoresist will begin to burn. Consequently, the use of photoresist as a hard mask is limited to low temperature plasma etching processes where the processing temperatures is less than approximately 150° C.

Therefore, in high temperature plasma etching processes, hard masks made from Titanium (Ti) and titanium nitride (TiN) have been widely used, especially as a hard mask for noble metals, such as platinum (Pt), ruthenium (Ru), and iridium (Ir), for example. Titanium (Ti) and titanium nitride (TiN) have also been used as a hard mask for conductive metal oxide materials (CMO). Examples of CMO materials include perovskites such as PCMO and LNO. The inherent etch properties of noble metals and CMO require a high temperature plasma etching processes to ensure a reasonable feature profile and to minimize residue formation due to by-product re-deposition on the surface of the film being etched. It is well understood in the microelectronics art that low temperature plasma etching of noble metals and CMO materials produces a non-volatile by-product. It is also well understood in the microelectronics art that temperature (e.g., a high temperature) is a key process parameter that can be used to control the re-deposition of by-products.

Although high processing temperatures can operate to limit re-deposition of etch by-products, the high processing temperatures can also accelerate chemical reactions, such as oxidation of materials exposed to the etch plasma at high temperatures, for example. During a high temperature plasma etching process, thin films of Ti, TiO, or TiN can be exposed to the plasma, where chemical processes such as ionization, recombination, and dissociation are constantly occurring. Consequently, those films become oxidized and as the oxidation continues, those films become increasingly resistant to the plasma etch process. Moreover, the oxidation of those films accelerates when oxygen (O₂) is introduced into the plasma etch environment, either as a gas mixed in with the etch gas or in an oxygen (O₂) containing material (e.g., SiO₂). Examples include Ti oxidizing into TiO₂ and TiN oxidizing into TiON. One consequence of the oxidation process is that TiO₂ and TiON become resistant to chemical etching, physical etching (e.g., plasma etching), and ion etching (e.g., ion bombardment).

The oxidation process can be exacerbated by process variables such as temperature and oxygen (O₂) content, for example. Higher temperatures accelerate the oxidation process; whereas, increasing oxygen (O₂) content in the etching environment exponentially increases in the oxidation process. The TiO₂ or TiON can form a residue that covers and shields an underlying layer from the plasma etch process. Therefore, the TiO₂ or TiON can serve as a secondary mask layer that protects the underlying layer during the plasma etching in much the same manner as a hard mask. As the plasma etching proceeds through the underlying layer, a portion of the underlying layer that is covered by the secondary mask is not etched away and remains on a subsequent layer. As a result, a residue forms on the subsequent layer. Eventually, when the plasma etching process terminates, the residue can remain on a bottom most layer and that residue can result in a yield reducing defect in a device.

In FIG. 1A, a conventional plasma etching process is used to etch a stack of thin film materials 100 through a hard mask 101. Examples of materials for the hard mask 101 include silicon nitride (Si₃N₄) and silicon oxide (SiO₂). The stack of thin film materials 100 includes a layer 103 of a titanium material, such as the aforementioned titanium (Ti), titanium oxide (TiO), or titanium nitride (TiN) thin films, for example. Below the layer 103 is a layer 105. The layer 105 can be a noble metal, such as platinum (Pt), ruthenium (Ru), or iridium (Ir), for example. A subsequent layer 107 can also be a titanium material as described above. For example, if the layer 105 is made of platinum (Pt), the layers 103 and 107 can be an adhesion layer. A layer 109 can be a dielectric layer (e.g. SiO₂) and can function as an etch stop layer. A layer 121 can be a semiconductor substrate, such as a silicon (Si) wafer, for example.

Although not shown, the hard mask 101 can be a layer of material that is deposited on the layer 103 and is subsequently patterned and etch to form the hard mask 101. In FIGS. 1A and 1B, an etch plasma p selectively etches the layer 103 during a plasma etch process as depicted by the dashed arrows in FIGS. 1A and 1B. The etch materials for the plasma p can be selected so that the etch process is anisotropic and results in two discrete thin film stacks (see reference numerals 104 in FIG. 1D) being formed as the plasma etch proceeds as depicted by heavy dashed lines 102. As the etch proceeds, oxygen (O₂) in the plasma p and/or the hard mask 101, chemically reacts with the titanium material in the layer 103. A chemical reaction between the etch materials in the plasma p (e.g., the O₂) and the titanium material in the layer 103 forms a thin layer of a titanium oxide (TiO₂) residue 103r. The residue 103r is resistant to the etch materials in the plasma p and serves as a secondary hard mask. Moreover, the oxidation process caused by the oxygen in the plasma p can be accelerated by heating h the stack 100 to a high temperature. For some materials, such as the aforementioned noble metals, high temperature processing is necessary for the plasma etching process to effectively etch the material with a desired profile. Although the plasma p is selective to the layer 103, the residue 103r is highly resistant to the plasma p and is not dissolved by the etch materials in the plasma p. Consequently, as the plasma p etches through the layer 103, the residue 103r continuously forms and propagates in a direction 103p along a receding surface of the layer 103 as depicted in FIG. 1B. Eventually, the residue 103r is positioned over the layer 105 and partially shields a portion of the layer 105 from the plasma p.

In FIG. 1C, the shielding by the secondary hard mask results in a residue 105r forming in the layer 105. The residue 105r serves as a secondary hard mask and propagates 105p in the direction of the etching. Finally, in FIG. 1D, when the etching process has ended, a residue 115r resides on the layer 109. The residue 115r can cause defects or contamination that can reduce device yields. For example, the residue 115r can include materials from some or all of the layers that preceded the layer 109. If any of the preceding layers included an electrically conductive material (e.g. platinum Pt in the layer 105), then the residue 115r can create an electrical short between adjacent thin film stacks 104.

Sources for the oxygen (O₂) that cause the oxidation of the titanium material include the etch gasses used for the plasma p and/or the thin film materials in the stack 100. The hard mask 101 can be an oxygen (O₂) containing material O₂ (e.g., silicon oxide SiO₂). Examples of etch gasses that the oxygen (O₂) can be a component of include but are not limited to argon (Ar), chlorine (Cl₂), boron trichloride (BCl₃), and fluorinated gasses (CFₓ).

There are continuing efforts to improve etch chemistry and etch processes for plasma etching of thin film materials.

### BRIEF DESCRIPTION OF THE DRAWINGS

FIGS. 1A through 1D depict a conventional plasma etching process using a plasma containing oxygen;

FIG. 2 is a flow chart depicting one embodiment of an oxygen depleted plasma etching process;

FIG. 3 is a flow chart depicting an alternative embodiment of an oxygen depleted plasma etching process;

FIGS. 4A through 4C depict a patterning and a developing of a mask layer to form an etch mask on an oxygen free hard mask layer;

FIGS. 4D through 4G depict an oxygen depleted etching of an oxygen free hard mask layer to form an oxygen free hard mask;

FIG. 4H depicts an oxygen free hard mask positioned on a stack of thin film materials;

FIGS. 4I through 4J depict an oxygen depleted plasma etching of a stack of thin film materials;

FIG. 5 is a flow chart depicting yet another embodiment of an oxygen depleted plasma etching process;

FIG. 6A depicts patterning a mask layer formed on an oxygen free hard mask layer that includes titanium;

FIG. 6B depicts an oxygen free plasma etching of the oxygen free hard mask layer depicted in FIG. 6A;

FIG. 6C depicts an oxygen free hard mask that includes titanium;

FIG. 6D depicts an oxygen depleted etching of a stack of thin film materials;

FIGS. 7A and 7B depict an embodiment of a mixed mode plasma etching process;

FIG. 8A depicts a patterning of a mask layer to form an etch mask on a hard mask layer;

FIG. 8B depicts a patterned mask layer for forming an etch mask on a composite hard mask layer;

FIG. 8C depicts a developing of a mask layer to form an etch mask.

FIGS. 8D through 8F depict an oxygen depleted plasma etching of a hard mask layer to form a hard mask;

FIG. 8G depicts an oxygen depleted plasma etching of a composite hard mask layer to form a hard mask;

FIG. 8H depicts an oxygen depleted plasma etching of a stack of thin film materials to a first predetermined layer in the stack;

FIGS. 8I through 8J depict an oxygen containing plasma etching of a stack of thin film materials to a second predetermined layer in the stack;

FIGS. 8K through 8M depict an oxygen depleted plasma etching of a stack of thin film materials to a third predetermined layer in the stack;

FIG. 9A depicts a stack of thin film materials that includes a very thin layer of a dielectric material positioned between layers in the stack; and

FIG. 9B depicts an oxygen depleted plasma etching of the stack of thin film materials of FIG. 9A.

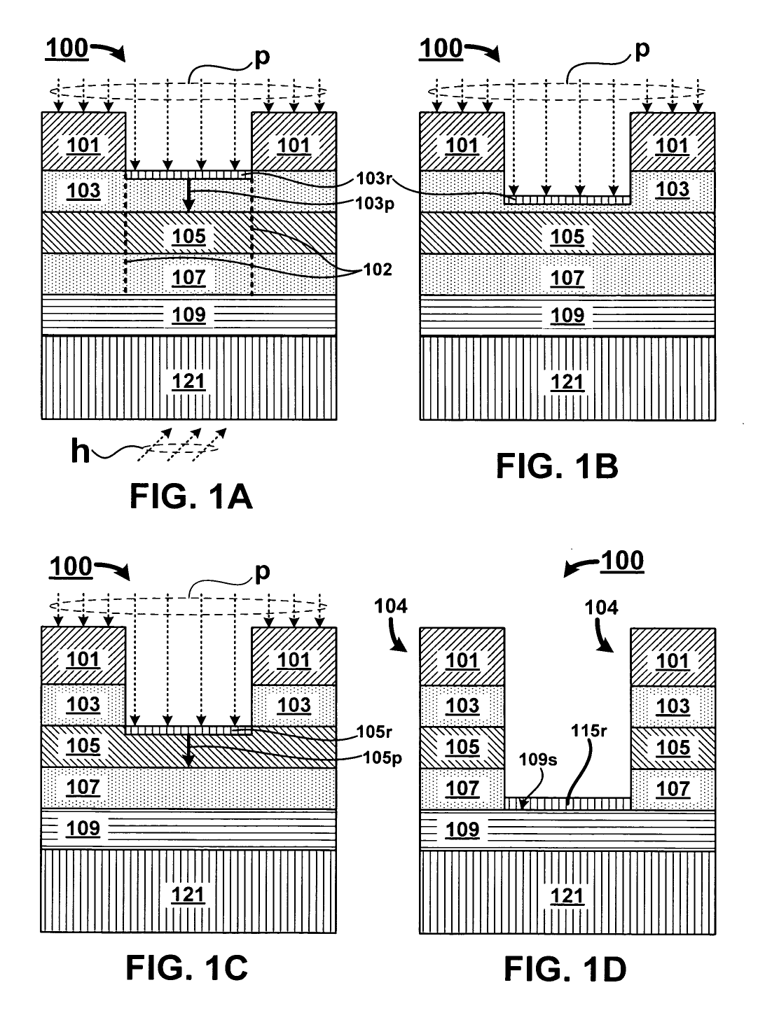

Although the previous Drawings depict various examples of the invention, the invention is not limited by the depicted examples. Furthermore, the depictions are not necessarily to scale.

### DETAILED DESCRIPTION

In the following detailed description and in the several figures of the drawings, like elements are identified with like reference numerals.

As shown in the drawings for purpose of illustration, the present invention is embodied in a method of oxygen depleted etching of thin films at a high temperature. In a first embodiment, the method includes forming a mask layer on an oxygen free hard mask layer, patterning the mask layer, developing the mask layer to form an etch mask on the oxygen free hard mask layer, etching the oxygen free hard mask layer in an oxygen free etch plasma to form an oxygen free hard mask, optionally removing the etch mask, etching a stack of thin film materials patterned by the oxygen free hard mask in an oxygen free etch plasma at a high temperature, and terminating the etching at a predetermined layer in the stack of thin film materials.

In a second embodiment, the method includes forming a mask layer on a hard mask layer that is not oxygen free, patterning the mask layer, developing the mask layer to form an etch mask on the hard mask layer, etching the hard mask layer in a substantially oxygen free etch plasma to form a hard mask, optionally removing the etch mask, etching a stack of thin film materials patterned by the hard mask in a substantially oxygen free etch plasma at a high temperature, and terminating the etching at a predetermined layer in the stack of thin film materials.

In a third embodiment, the method includes forming a mask layer on an oxygen free titanium hard mask layer, patterning the mask layer, developing the mask layer to form an etch mask on the oxygen free titanium hard mask layer, etching the oxygen free titanium hard mask layer in an oxygen free etch plasma to form an oxygen free titanium hard mask, etching a stack of thin film materials patterned by the oxygen free titanium hard mask in an oxygen free etch plasma at a high temperature, and terminating the etching at a predetermined layer in the stack of thin film materials.

In a fourth embodiment, a mixed mode method includes forming a mask layer on a hard mask layer, patterning the mask layer, developing the mask layer to form an etch mask on the hard mask layer, etching the hard mask layer in a first oxygen free etch plasma to form a hard mask, etching a stack of thin film materials patterned by the hard mask in the first oxygen free etch plasma at a high temperature, terminating the etching at a first predetermined layer in the stack of thin film materials, continuing to etch the stack in a second oxygen containing etch plasma at a high temperature, terminating the etching at a second predetermined layer in the stack, continuing to etch the stack in a third oxygen free etch plasma at a high temperature, and terminating the etching at a third predetermined layer in the stack.

An Oxygen Free Hard Mask

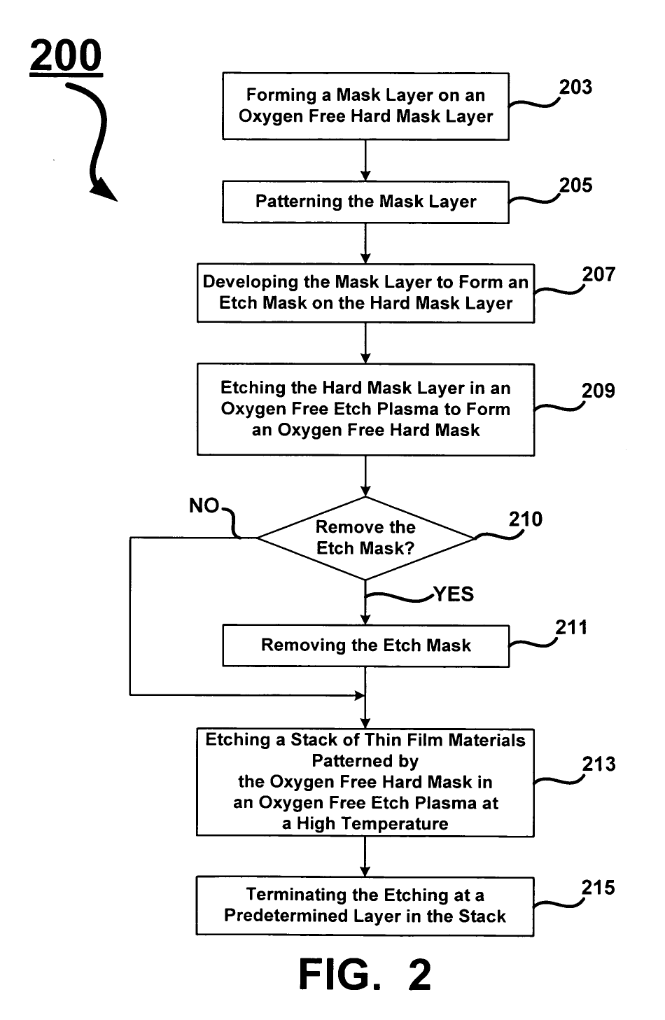

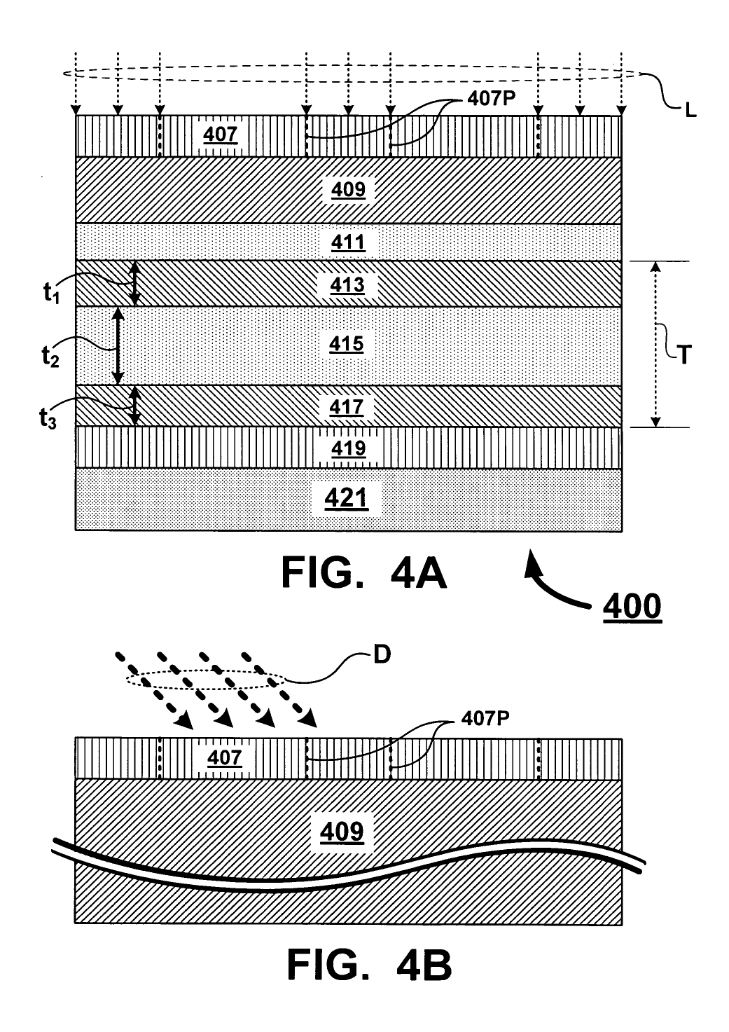

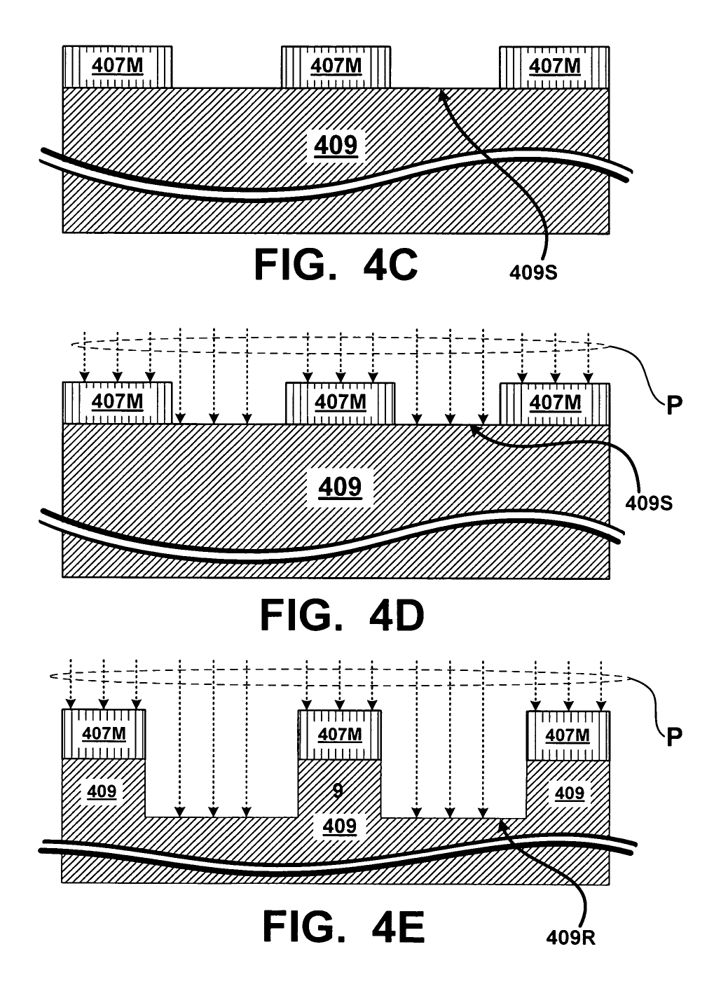

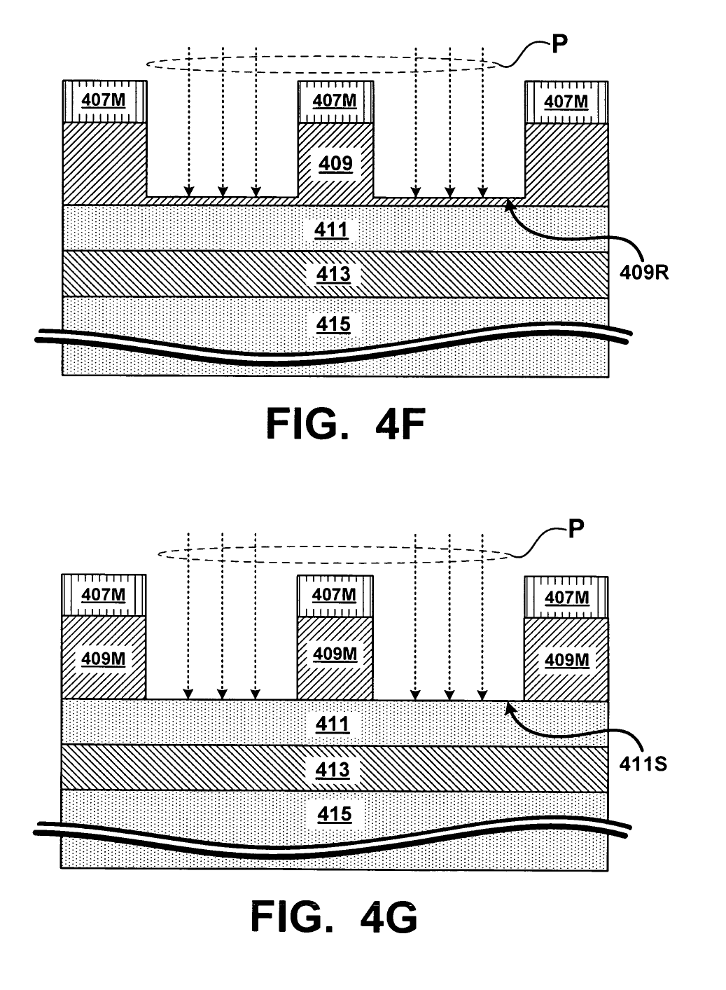

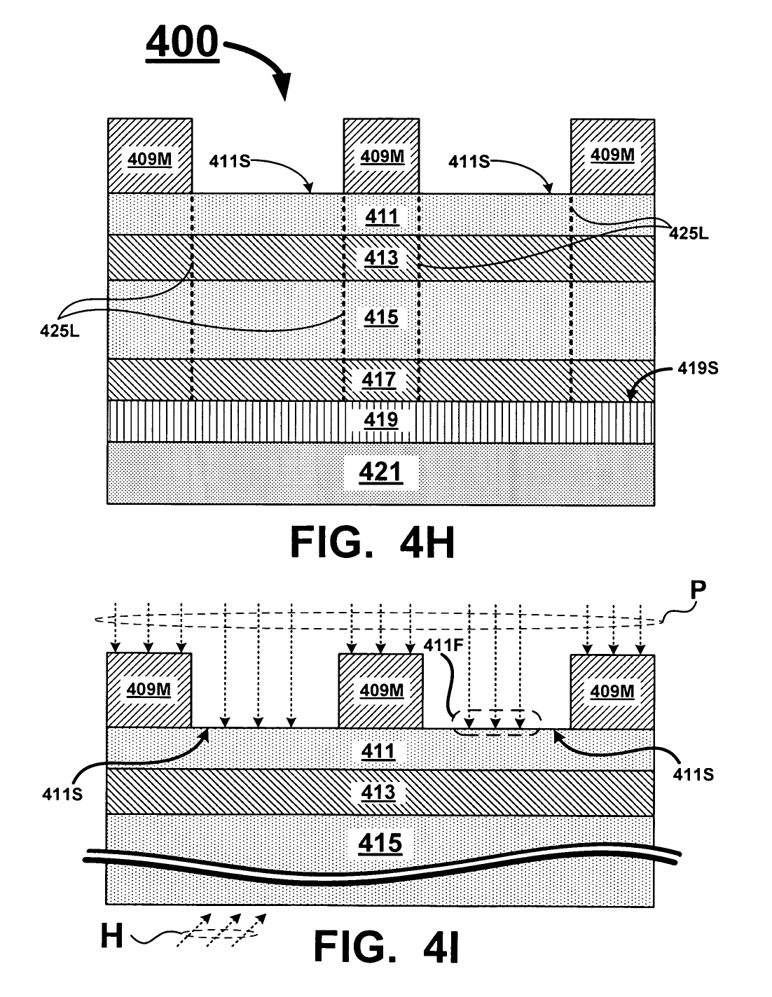

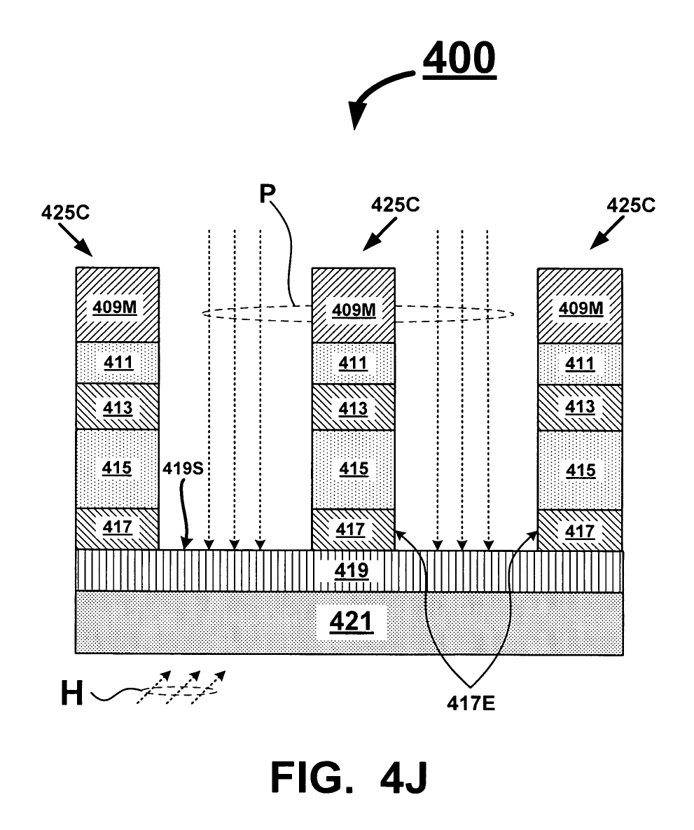

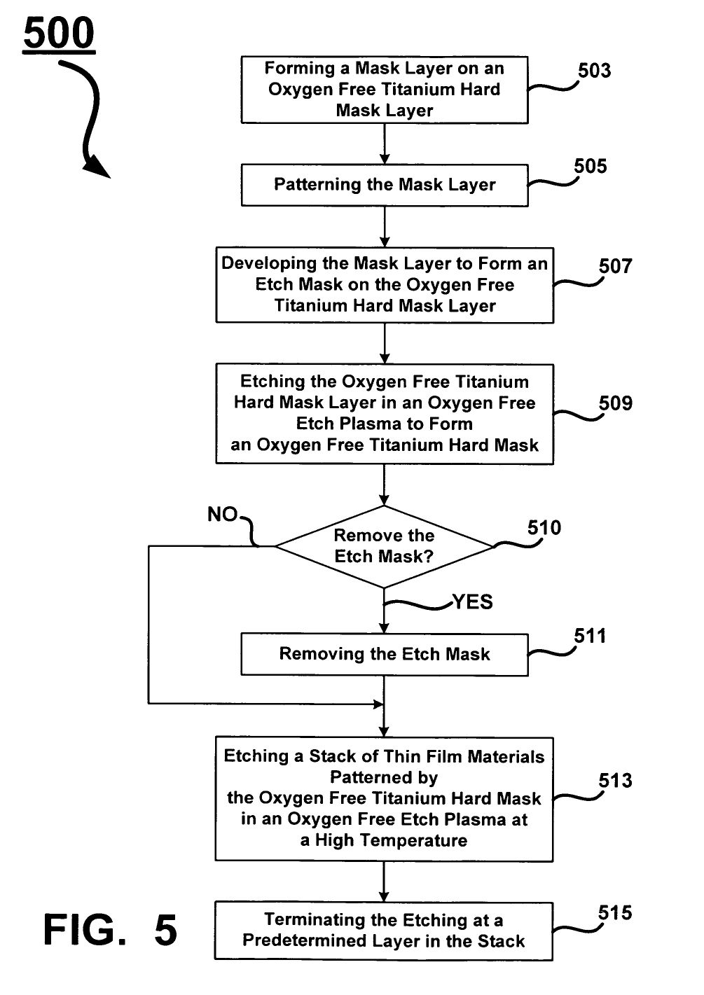

Referring now to FIG. 2 and FIGS. 4A through 4C, a method 200 of oxygen depleted etching includes, at a stage 203, forming a mask layer 407 on an oxygen (O₂) free hard mask layer 409. Preferably, the hard mask layer 409 is made from an electrically non-conductive material. At a stage 205, the mask layer 407 is patterned. At a stage 207, the mask layer 407 is developed to form an etch mask 407M on the hard mask layer 409. The forming, patterning, and developing of the mask layer 407 can be accomplished using processes that are well understood in the microelectronics art. For example, the mask layer 407 can be a photoresist material that is spin deposited on a surface of the hard mask layer 409. Photolithography can be used to expose a pattern 407P in the mask layer 407 using light L (see FIG. 4A). Subsequently, the mask layer 407 can be developed D using a wet or a dry etching process to form the etch mask 407M (see FIG. 4C). If dry etching (e.g. plasma etching) is used to develop the mask layer 407, then a temperature in the plasma environment should be within an acceptable range of temperatures for the material selected for the mask layer 407. Therefore, if the mask layer 407 is a photoresist material, then the temperature should be adjusted to an appropriate temperature range. Typically, a temperature of approximately 150° C. or less is suitable for plasma etching of photoresists. More preferably, the temperature is approximately 100° C. or less for photoresist materials. For example, the plasma etching can occur at approximately room temperature (e.g., about 25° C.).

Turning now to FIGS. 4D through 4G, after the etch mask 407M is formed, at a stage 209, the hard mask layer 409 is etched in an oxygen (O₂) free etch plasma P to form a hard mask 409M. As the plasma etch proceeds, a surface 409S of the mask layer 409 that is not covered by the etch mask 407M, recedes 409R in a direction towards an underlying layer 411. The plasma etching can be halted when a surface 411S of the underlying layer 411 is exposed. Endpoint detection techniques that are well understood by those skilled in the microelectronics art can be used to determine when to terminate the etching at the stage 209. Determining the endpoint for terminating the etching at the stage 209 can include but is not limited to techniques such as etch time, spectral analysis of a light spectra emitted by the oxygen free plasma P, the use of a material suitable as an etch stop layer, and chemical analysis of the plasma P to detect one or more constituent compounds in the oxygen free plasma P that are indicative of having reached the endpoint, for example.

At a stage 210, the etch mask 407M may optionally be removed from the hard mask 409M. The decision to remove the etch mask 407M can be based on the material used for the etch mask 407M and its ability to withstand high temperatures in a subsequent plasma etching process at a stage 213. If the etch mask 407M is made from a photoresist material or some other material that cannot withstand high temperature processing, then at a stage 211, the etch mask 407M can be removed from the hard mask 409M. For example, if the etch mask 407M is a photoresist material, then an ashing or stripping process can be used to remove the etch mask 407M. If ashing is used, it is preferable that the ashing process is also oxygen free because the underlying layer 411 can be made from a material that includes titanium or an alloy of titanium that can be oxidized if exposed to oxygen. On the other hand, if the etch mask 407M can withstand high temperature processing, then the etch mask 407M need not be removed and the stage 211 can be skipped. However, one skilled in the art will appreciate that the etch mask 407M may need to be removed to achieve some other process related goal. Therefore, the stage 211 may be implemented to achieve that processing goal.

In FIG. 4G, the oxygen free hard mask 409M is positioned on the surface 411S of the underlying layer 411. The underlying layer 411 is one of a plurality of thin film layers in a stack 400 of thin film materials. The hard mask 409M will be used to etch through the plurality of thin film layers in the stack 400 that are positioned below the hard mask 409M as depicted by heavy dashed lines 425L in FIG. 4H. The hard mask 409M opening process using an oxygen free etch plasma P is critical in preventing a formation of a highly etch resistant secondary mask layer proximate the surface 411S of the underlying layer 411. By eliminating oxygen (O₂) from the material for the hard mask layer 409 and from the plasma P, titanium (Ti) or an alloy of titanium in the layer 411 will not form oxides of titanium (e.g., TION or TiO₂) on the surface 411S that will serve as the highly etch resistant secondary mask layer.

In FIG. 4I, at a stage 213, exposed layers in the stack 400 are plasma etched through the openings in the hard mask 409M using an oxygen (O₂) free etch plasma P at a high temperature H. The layer 411 is the first layer to be etched, followed by the layers positioned below it. For the same reasons stated above, the oxygen (O₂) free etch plasma P prevents by-product re-deposition of oxides of titanium on exposed etch surfaces so that a secondary hard mask layer is not formed. Therefore, a portion 411F of the surface 411S of the layer 411 is free of oxides of titanium that can mask subsequent layers in the stack 400 from being etched by the plasma P.

In FIG. 4J, at a stage 215, the etching terminates at a predetermined layer in the stack 400. In FIG. 4J, the etching terminates at a surface 419S of a layer 419 in the stack 400. The termination at the stage 215 can be controlled by process parameters such as time or a selection of an appropriate endpoint indicator, for example. As one example, the etching can run for a predetermined period of time and can be halted at the stage 215. As another example, the plasma P can be monitored by a sensor and an output from the sensor can be coupled with a computer or process controller to determine that an endpoint for the stage 215 has been reached. The sensor can analyze the gasses in the plasma P or a light spectra of the plasma P to detect a condition indicative of the endpoint that triggers termination at the stage 215.

On the other hand, the layer 419 can be made from a material that serves as an etch stop layer that is resistant to the etch plasma P. For example, the layer 419 can be made from a dielectric material, such as silicon nitride (Si₃N₄) or silicon oxide (SiO₂). After the stage 215, the layers in the stack 400 form discrete columns of thin film materials 425C. Each discrete column 425C can represent an active device, such as a resistive state memory device, for example. The elimination of by-product re-deposition of oxides of titanium during the plasma etching at stages 209 and 213 can prevent or substantially eliminate secondary mask layer propagation downward in the stack 400 as the etching proceeds so that masking effects of a secondary mask layer does not result in a residue forming on the surface 419S.

One possible consequence of not preventing secondary mask layer formation is that electrically conductive residue can form and create defects or electrical shorts. For example, if an electrically conductive residue is present on the surface 419S, then a conductive path between sidewall surfaces 417E of a layer 417 can be formed by the residue, creating a short circuit between the adjacent discrete columns 425C. If the adjacent columns 425C define active electrical devices, then those devices can be rendered inoperative due to the short circuit path electrically coupling the devices to each other.

The layers of thin film materials in the stack 400 will be application dependent and the stack 400 can include more layers or fewer layers than depicted in FIG. 4A. TABLE 1 below lists examples of materials that can be used for the layers in the stack 400. In the examples listed in TABLE 1, the layer 411 can be a titanium (Ti) glue or adhesion layer between the hard mask layer 409 and a noble metal layer 413. The stack 400 can be fabricated using thin film deposition processes to build the layers up from a substrate layer 421.

TABLE 1

| Layer | Example Materials |
|---|---|
| 407 | An O₂ Free Etch Mask Material (e.g., photoresist) |
| 409 | An O₂ Free Hard Mask Material including an O₂ Free Dielectric |
| | Material |
| 411 | titanium (Ti) or an alloy of titanium: (e.g., Ti, TiN, or TiO) |
| 413 | A noble metal or an alloy of a noble metal: |
| | (e.g., platinum (Pt), ruthenium (Ru), or iridium (Ir)) |
| 415 | A Conductive Metal Oxide (CMO) (e.g., a perovskite, PCMO, or |
| | LNO) |
| 417 | A noble metal or an alloy of a noble metal: |
| | (e.g., platinum (Pt), ruthenium (Ru), or iridium (Ir)) |
| 419 | An Electrically Nonconductive Layer: |
| | (e.g. a dielectric layer, Si₃N₄, or SiO₂) |
| 421 | A Substrate: (e.g., a semiconductor, silicon (Si), |
| | single crystal Si, or a Si wafer) |

Preferably, a total thickness T of the layers 413, 415, and 417 is less than approximately 1500 Å (see FIG. 4A). For example, a thickness t₁, t₂, and t₃ of the layers 413, 415, and 417 respectively, can be approximately 500 Å or less so that the total thickness T of the three layers is less than approximately 1500 Å. The aforementioned residue formation due to by-product re-deposition is more common when a thickness of the thin film (e.g., a noble metal) is approximately 500 Å or less. On the other hand, when the total thickness T of the thin film layer is on the order of thousands of angstroms, then there is a higher probability of the secondary mask layer (e.g., TiO₂ or TiON) being cleared away during the etching of the thin film layer (e.g., a layer of Pt). Therefore, in some applications, it may not be useful to use the oxygen depleted etch process for layer thicknesses on the order of thousands of angstroms (e.g., T>1500 Å).

An Oxygen Containing Hard Mask

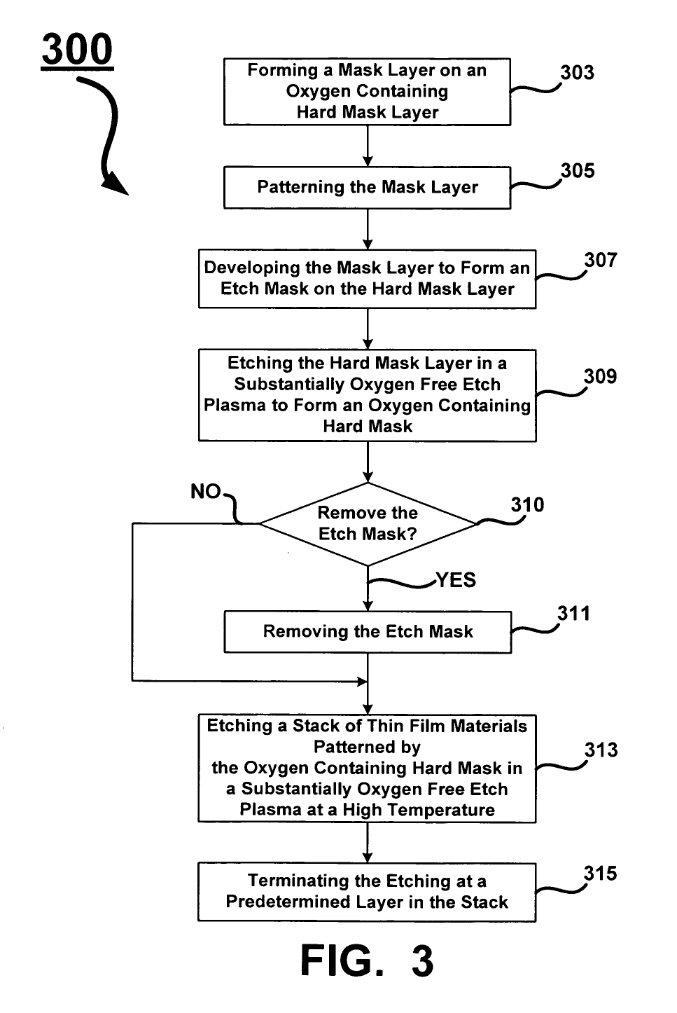

Referring now to FIG. 3 and FIGS. 4A through 4C, a method 300 of oxygen depleted etching includes, at a stage 303, forming the mask layer 407 on the hard mask layer 409 in the stack 400 of thin film layers. However, unlike the method 200 as described above, in the method 300, the hard mask layer 409 is not oxygen (O₂) free. Instead, the hard mask layer 409 is an oxygen (O₂) containing material. For example, the hard mask layer 409 can be an electrically nonconductive material such as silicon oxide (SiO₂). Alternatively, the hard mask layer 409 can be an electrically conductive material such as titanium oxide (TiO), for example. At a stage 305, the mask layer 407 is patterned 407P. At a stage 307, the mask layer 407 is developed to form the etch mask 407M (see FIGS. 4B and 4C). At a stage 309, the hard mask layer 409 is etched in a substantially oxygen (O₂) free etch plasma P to form a hard mask 409M (see FIGS. 4D-4G). Optionally, at a stage 310, the etch mask 407M can be removed at a stage 311 as was described above or the method 300 can continue at a stage 313.

At the stage 313, exposed layers in the stack 400 are plasma etched through the openings in the oxygen containing hard mask 409M using a substantially oxygen (O₂) free etch plasma P at a high temperature H. Although the etch plasma P at the stages 309 and 313 is initially oxygen free because oxygen (O₂) is not intentionally included in the etch gasses that form the plasma P, chemical processes caused by the plasma P reacting with the hard mask 409M can liberate some of the oxygen (O₂) from the hard mask 409M. Therefore, during the stages 309 and 313, some of the oxygen (O₂) in the hard mask 409M can be introduced into the plasma P. As a result, the plasma P is not totally free of oxygen (O₂). However, the amount of oxygen (O₂) introduced into the plasma P is substantially lower than the case where oxygen (O₂) is intentionally introduced into the plasma P as one of the etch gasses. Therefore, any residual oxygen (O₂) remaining in the plasma P during the etching of the stack 400 results in a substantially oxygen free etch plasma P. At a stage 315, the etching can be terminated at a predetermined layer in the stack 400 as was described above.

Oxygen Free Titanium Hard Mask

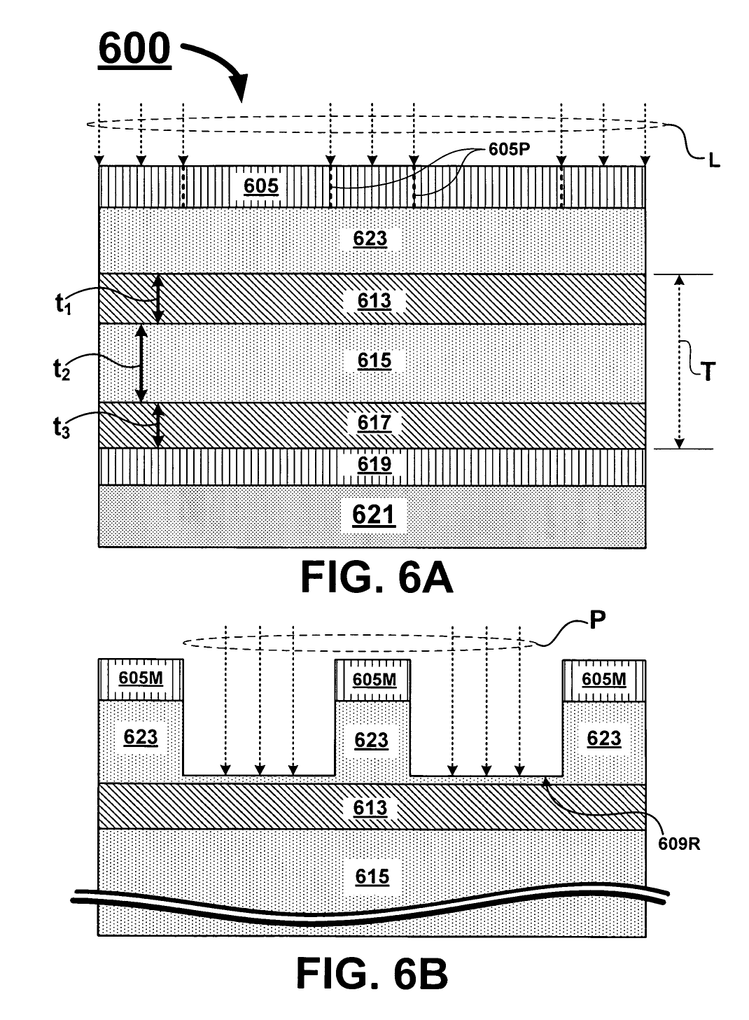

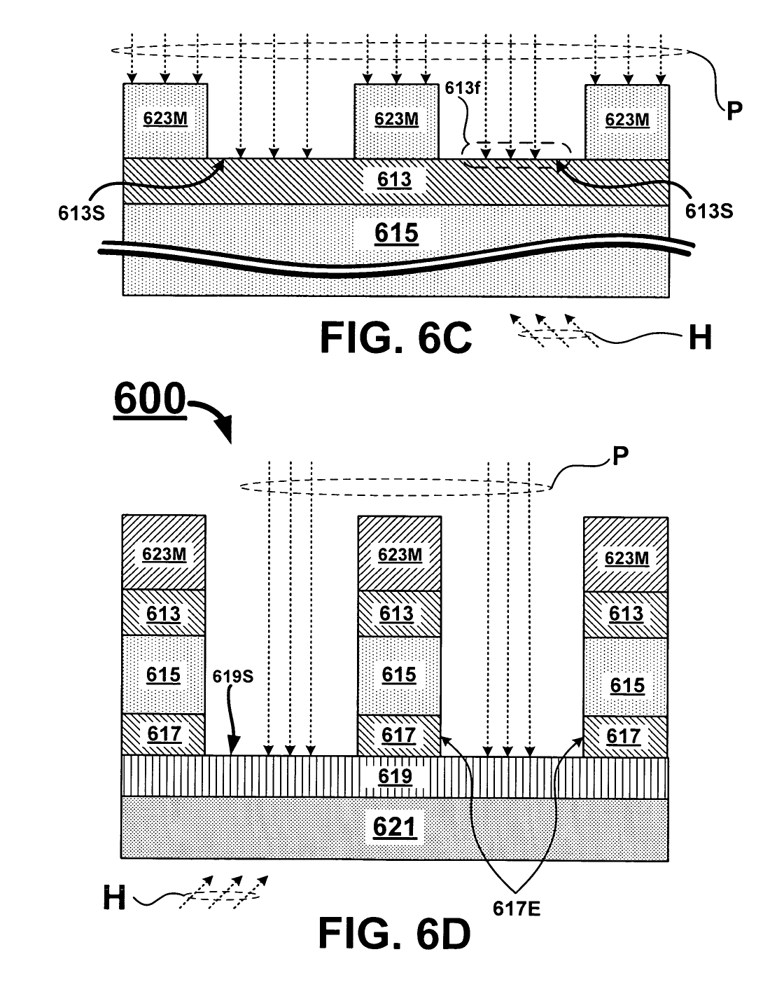

Turning to FIG. 5 and FIGS. 6A through 6D, a method 500 of oxygen depleted etching includes, at a stage 503, forming a mask layer 605 on an oxygen free titanium hard mask layer 623. The oxygen free titanium hard mask layer 623 can include other materials or compounds and need not be a titanium (Ti) only layer. At a stage 505, the mask layer 605 is patterned 605P. At a stage 507, the mask layer 605 is developed to form an etch mask 605M. At a stage 509, the oxygen free titanium hard mask layer 623 is etched in an oxygen free etch plasma P to form an oxygen free titanium hard mask 623M. Optionally, at a stage 510, the etch mask 605M can be removed at a stage 511 as was described above or the processing can continue at a stage 513. At the stage 513, exposed layers in a stack 600 of thin film materials are etched through the openings in the oxygen free titanium hard mask 623M using an oxygen free etch plasma P at a high temperature H. At a stage 515, the etching can be terminated at a predetermined layer in the stack 600 as was described above.

One advantage to the oxygen free titanium hard mask 623M is that it can serve as both a hard mask and an adhesion layer or glue layer for an underlying noble metal layer 613. In some applications, the oxygen free titanium hard mask 623M can be used instead of a dedicated adhesion/glue layer, such as the layer 411 in FIG. 4A, for example. The layers of thin film materials in the stack 600 will be application dependent and the stack 600 can include more layers or fewer layers than depicted in FIG. 6A. However, TABLE 2 below lists examples of materials that can be used for the layers in the stack 600.

TABLE 2

| Layer | Example Materials |
|---|---|
| 605 | An O₂ Free Etch Mask Material (e.g., photoresist) |
| 623 | titanium (Ti) or an Alloy of titanium (e.g., TiN) |
| 613 | A noble metal or an alloy of a noble metal |
| | (e.g., platinum (Pt), ruthenium (Ru), or iridium (Ir)) |
| 615 | A Conductive Metal Oxide (CMO) (e.g., a perovskite, PCMO, or |
| | LNO) |
| 617 | A noble metal or an alloy of a noble metal |
| | (e.g., platinum (Pt), ruthenium (Ru), or iridium (Ir)) |
| 619 | An Electrically Nonconductive Layer |
| | (e.g., a dielectric material, Si₃N₄, or SiO₂) |
| 621 | A Substrate (e.g., a semiconductor material, |
| | silicon (Si), single crystal Si, or a Si wafer) |

Mix Mode Oxygen Depleted Plasma Etching

In some applications it may be desirable to use an etch chemistry that varies over the course of a plasma etching of a stack of thin film materials. Depending on the number of layers in the stack and the particular etching requirements for one or more layers in the stack, the etch gasses may be switched between an oxygen depleted etch gas (i.e., no O₂ is mixed with the etch gas) and oxygen containing etch gas (i.e., O₂ is intentionally added to the etch gas). Therefore, one or more layers in the stack may require etching with an oxygen depleted plasma and one or more layers in the stack may require etching with an oxygen containing plasma. Accordingly, a mixed mode etching process includes switching one or more times between oxygen depleted plasma etching and oxygen containing plasma etching. Each etching mode can be continued until a predetermined layer in the stack is reached. Upon reaching the predetermined layer, the etching mode may be switched from oxygen depleted to oxygen containing or vice-versa, or the plasma etching process can terminate at the appropriate layer in the stack or upon an endpoint condition. The composition of the etch gas can also be changed depending on the etch mode (i.e., oxygen depleted or oxygen containing). For the oxygen depleted plasma etching the etch gas can include Ar and Cl₂; whereas, for the oxygen containing plasma etching the etch gas can include Cl₂ and O₂, for example.

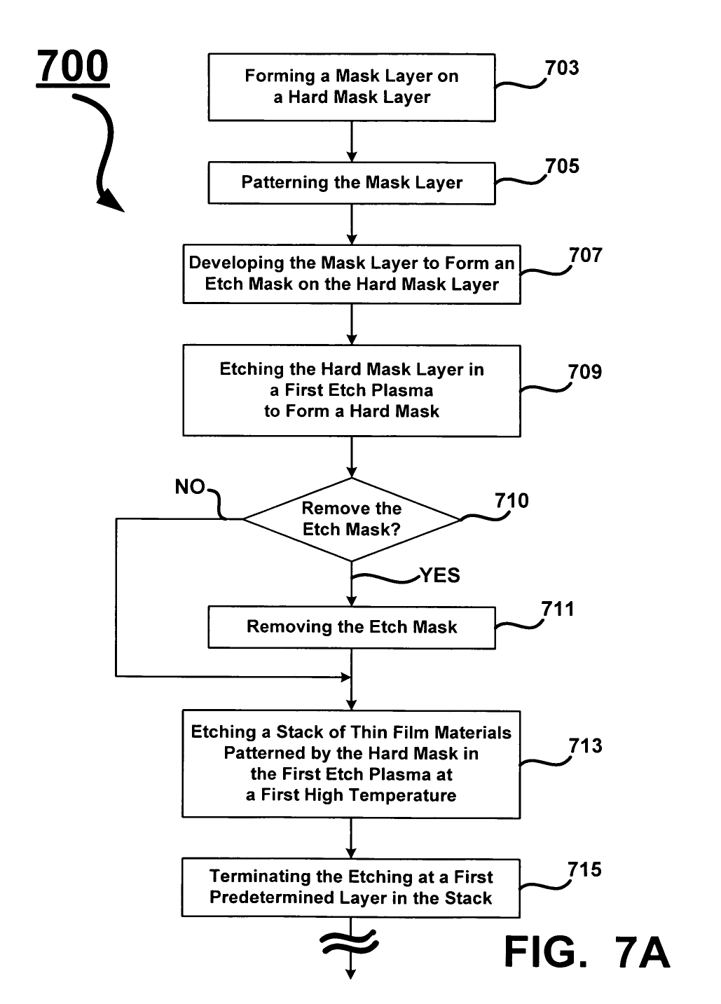

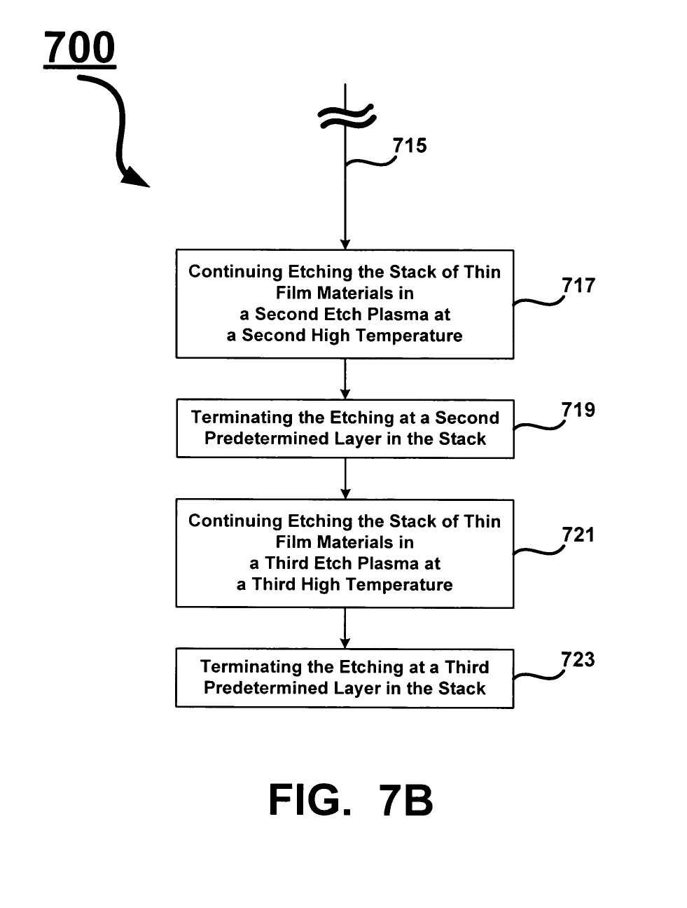

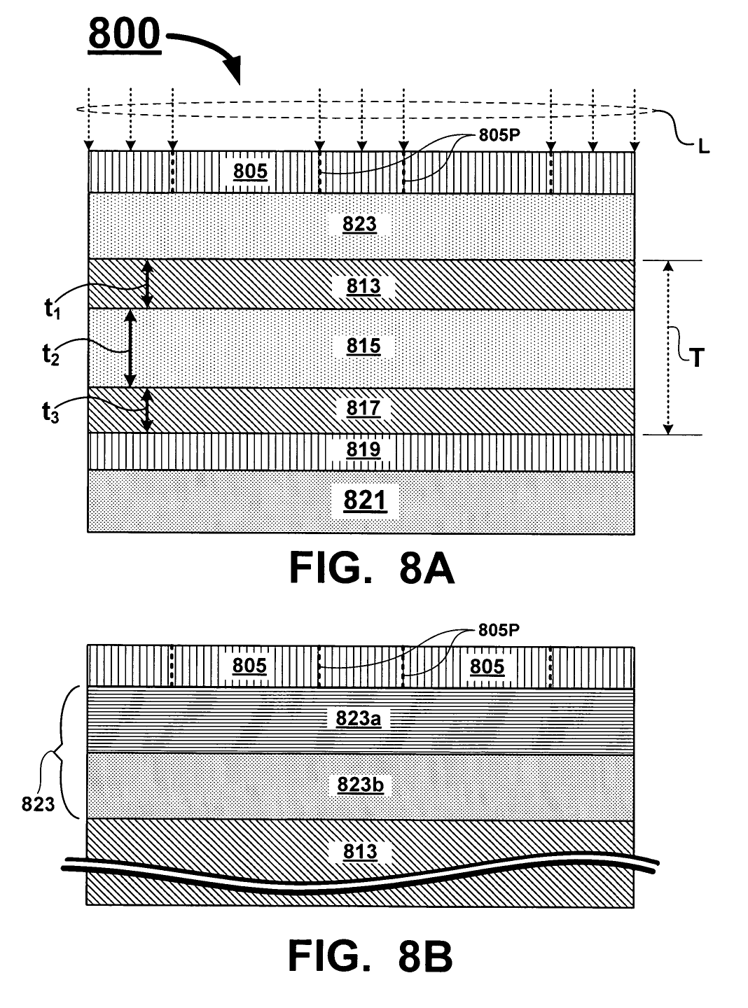

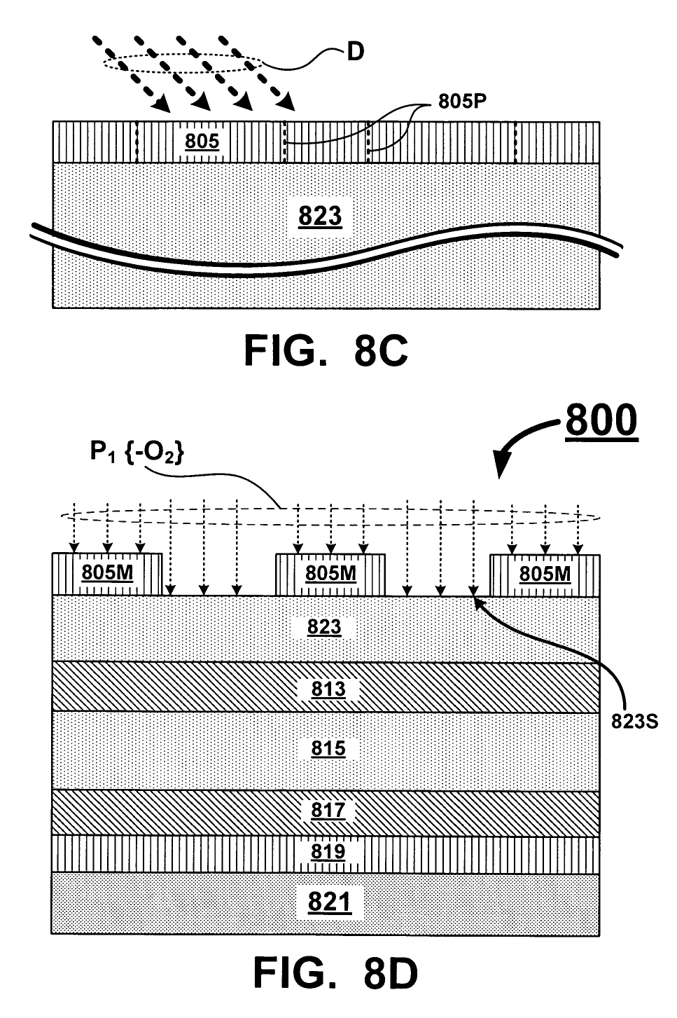

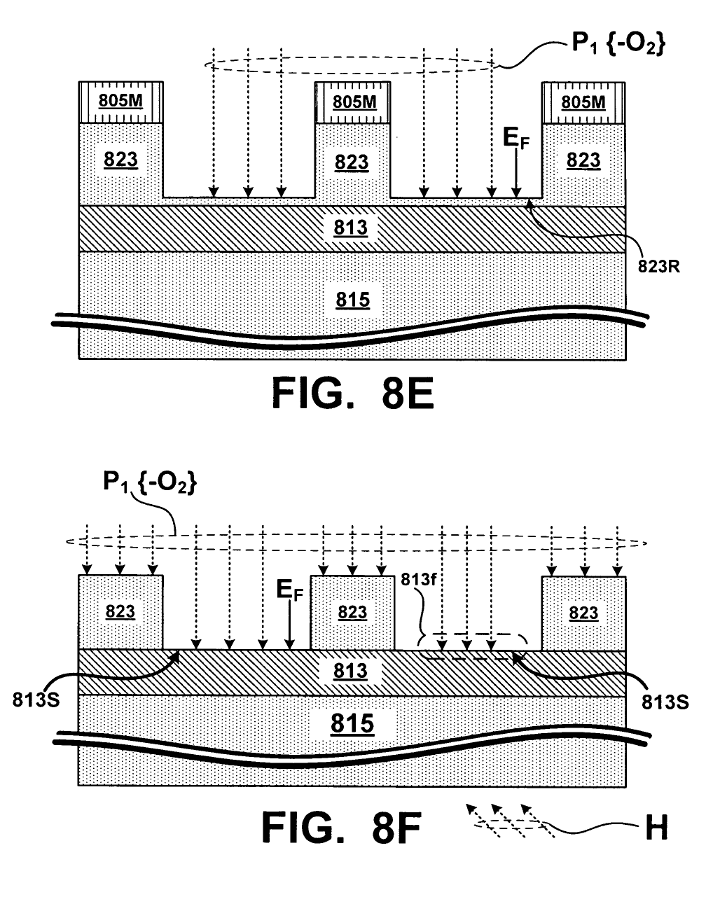

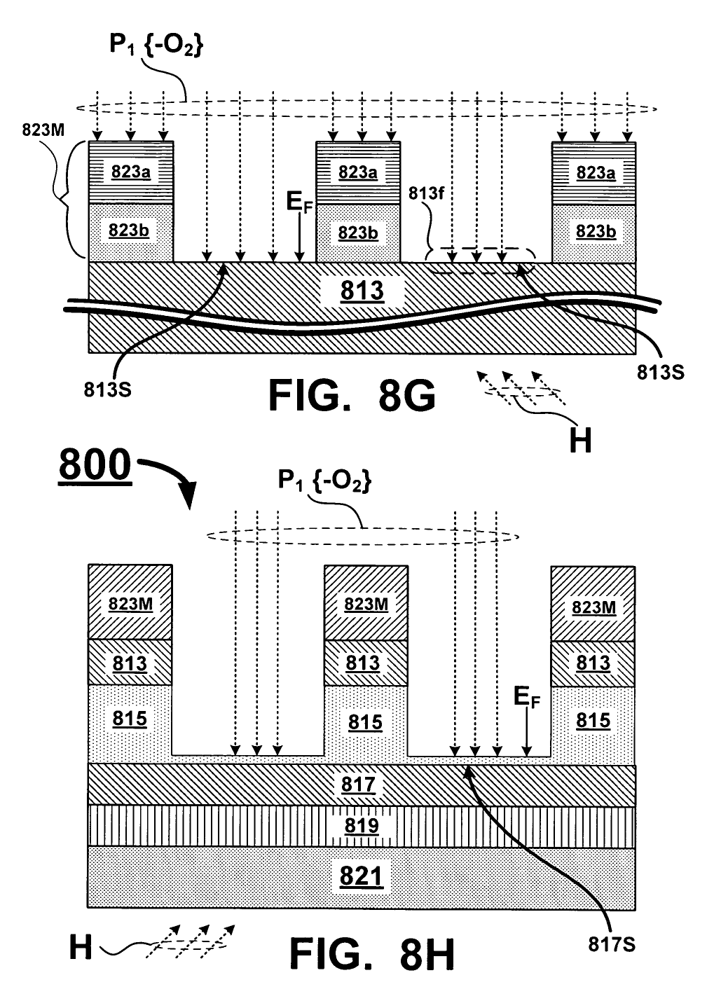

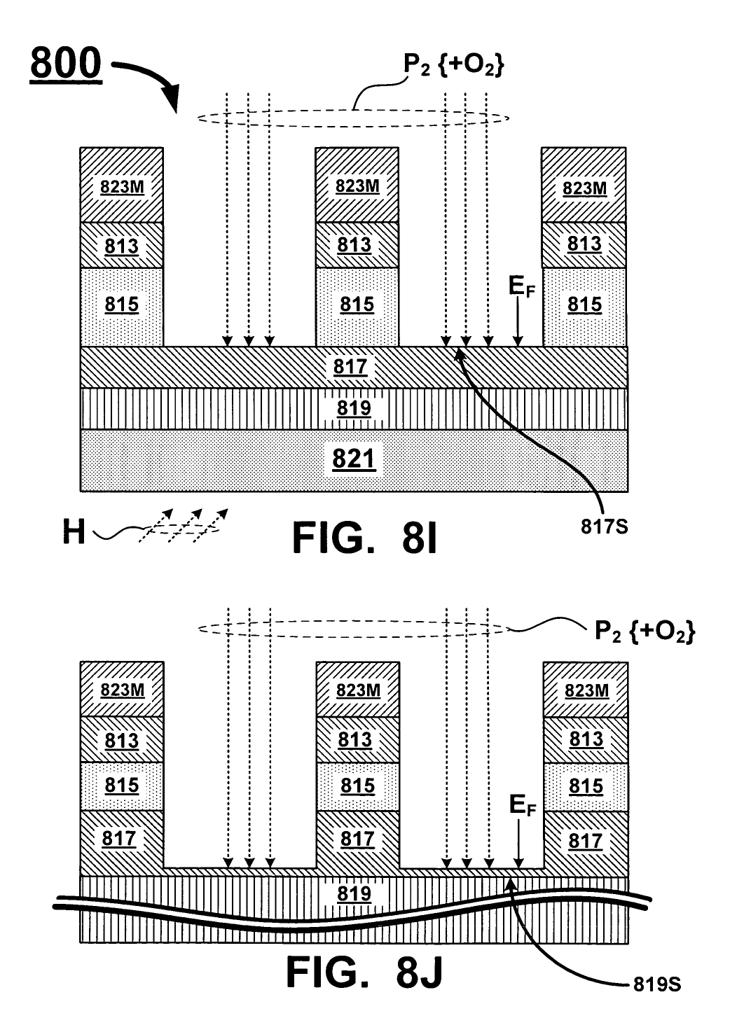

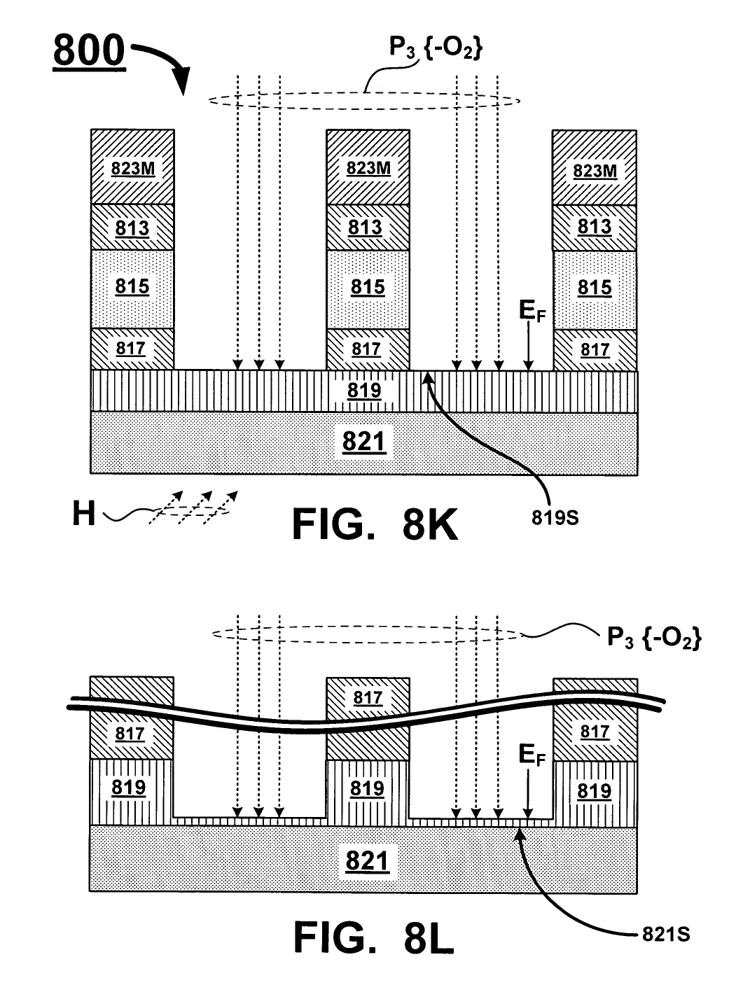

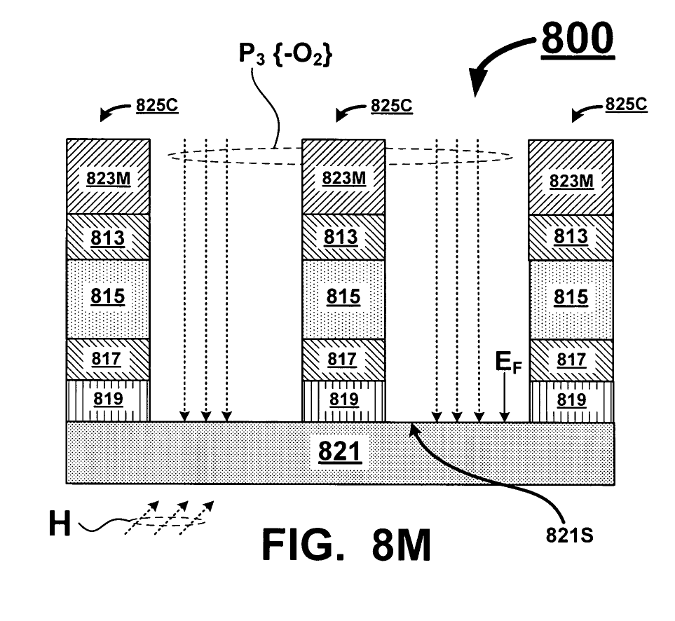

Reference is now made to FIGS. 7A and 7B and FIGS. 8A through 8M, where a method 700 for mixed mode plasma etching of a stack 800 of thin film materials includes at a stage 703, forming a mask layer 805 on a hard mask layer 823. The mask layer 805 is patterned at a stage 705 as depicted by dashed lines 805P, followed by developing D the mask layer 805 at a stage 707 (see FIG. 8C) to form an etch mask 805M (see FIG. 8D). The hard mask layer 823 can be a single layer of material as depicted in FIG. 8A (e.g., TiN or TiO₂) or the hard mask layer 823 can be a composite hard mask layer made from two or more layers of thin film materials that are suitable for use as a hard mask. FIG. 8B depicts a hard mask layer 823 that includes two layers 823a and 823b. In either case, the etch mask 805M will be used to etch through the single layer or the composite layer to form a hard mask. Examples of materials for the layer 823a include but are not limited to SiO₂ and SiN₃ and materials for the layer 823b include but are not limited to TiN and TiO₂.

Turning now to FIGS. 8D through 8E, at a stage 709, the hard mask layer 823 is etched in a first etch plasma P₁{−O₂} to form a hard mask. The etch gasses for the first etch plasma P₁{−O₂} does not contain oxygen (O₂). If the hard mask layer 823 is made from an oxygen free material, then the first etch plasma P₁{−O₂} is an oxygen free etch plasma because the material for the mask layer does not contribute oxygen to the plasma etch environment. The first etch plasma P₁{−O₂} etches the hard mask layer 823 through the etch mask 805M and a surface 823R of the hard mask layer 823 recedes in a direction towards an underlying layer 813. FIG. 8F depicts a hard mask 823 formed over the layer 813. FIG. 8G depicts an alternate scenario where the hard mask layer 823 comprises a composite layer (i.e., made from two or more layers of different materials) and the first etch plasma P₁{−O₂} results in a formation of a hard mask (823a, 823b) formed over the layer 813. Hereinafter, the hard mask will be denoted as 823M regardless of whether it is formed from a single layer (FIG. 8F) or multiple layers (FIG. 8G). As was described above, at a stage 710, the etch mask 805M may optionally be removed at a stage 711 or the first etch plasma P₁{−O₂} can continue at a stage 713. In FIG. 7A and FIGS. 8A and 8B, if the hard mask layer (823 or 823a and 823b) are oxygen containing layers (e.g., TiO₂), then the fist etch plasma P₁{−O₂} is a substantially oxygen free etch plasma. Therefore, at the stage 709, formation of the hard mask 823M by the first etch plasma P₁{−O₂} will be result in an oxygen free etch plasma or a substantially oxygen free etch plasma, depending on the composition of the mask layer 823.

In FIGS. 8H and 8I, at the stage 713, the first etch plasma P₁{−O₂} etches at a high temperature H, the stack 800 of thin film materials that are patterned by the hard mask 823M. At a stage 715, the etching is terminated at a first predetermined layer in the stack (e.g., a layer 817).

Turning now to FIGS. 7B and 8J, the method 700 continues at a stage 717 where the stack 800 of thin film materials is etched in a second etch plasma P₂{+O₂} at a high temperature H. At the stage 717, oxygen (O₂) is added to the etch gasses for the second etch plasma P₂{+O₂} such that the plasma is an oxygen containing plasma. At a stage 719, the etching is terminated at a second predetermined layer in the stack 800 (e.g., a layer 819). In FIG. 8K, at a stage 721, etching of the stack 800 continues with a third etch plasma P₃{−O₂} at a high temperature H and at a stage 723 the etching is terminated at a third predetermined layer in the stack 800 (e.g., a layer 821). At the stage 721, oxygen (O₂) is not added to the etch gasses for the third etch plasma P₃{−O₂} such that the plasma is an oxygen free etch plasma. The high temperature H need not be the same for the stages 713, 717, and 721.

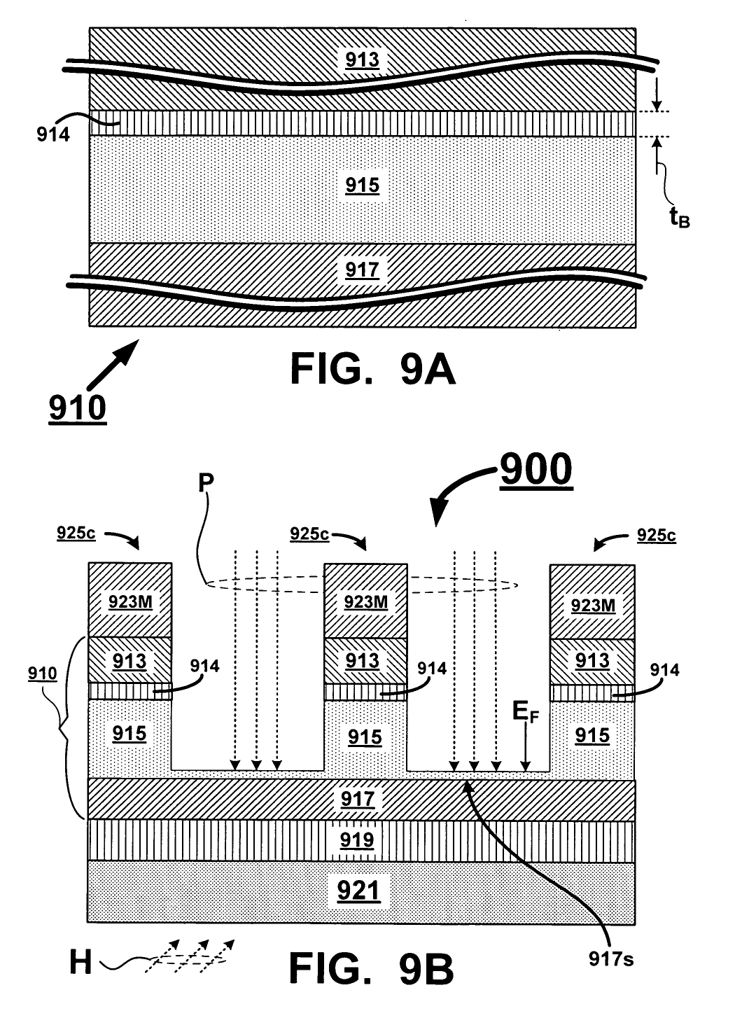

The stacks 400, 600, and 800 that were described above can include a wide variety of layered thin film materials. One of the layers can be a very thin layer of a dielectric material. In FIG. 9A, a layer 914 is sandwiched between layers 913 and 915. Preferably, the layer 914 has a thickness t_{B} that is approximately 30 Å or less. For example, the layer 914 can be a tunnel barrier layer, the layer 915 can be a CMO layer (e.g., a manganite, a perovskite, PCMO, or LNO) and the layer 913 can be a layer of an electrically conductive material such as a noble metal or an alloy of a noble metal (e.g., Pt, Ru, or Ir). A layer 917 can also be a layer of an electrically conductive material such as a noble metal or an alloy of a noble metal (e.g., Pt, Ru, or Ir). Collectively, the layers 913, 914, 915, and 917 can be a memory element 910 that stores data as a plurality of conductivity profiles. Although not depicted in FIGS. 9A and 9B, other layers in the stack 900 can include a plurality of thin film materials that form a metal-insulator-metal structure (e.g., a non-ohmic device) that is electrically in series with the memory element 910 and operative to impart a non-linear I-V characteristic so that the memory element 910 operates within a preferred range of voltages and currents for read and write operations to the memory element 910. U.S. patent application Ser. No. 11/095,026, filed Mar. 30, 2005, and titled “Memory Using Mixed Valence Conductive Oxides,” hereby incorporated by reference in its entirety and for all purposes, describes non-volatile memory cells that can be arranged in a cross-point array. The application describes a two terminal memory element that changes conductivity when exposed to an appropriate voltage drop across the two terminals. The memory element includes an electrolytic tunnel barrier and a mixed valence conductive oxide. A voltage drop across the electrolytic tunnel barrier causes an electrical field within the mixed valence conductive oxide that is strong enough to move oxygen ions out of the mixed valence conductive oxide and into the electrolytic tunnel barrier. When certain mixed valence conductive oxides (e.g., praseodymium-calcium-manganese-oxygen perovskites—PCMO and lanthanum-nickel-oxygen perovskites—LNO) change valence, their conductivity changes. Additionally, oxygen accumulation in certain electrolytic tunnel barriers (e.g., yttrium stabilized zirconia—YSZ) can also change conductivity. If a portion of the mixed valence conductive oxide near the electrolytic tunnel barrier becomes less conductive, the tunnel barrier width effectively increases. If the electrolytic tunnel barrier becomes less conductive, the tunnel barrier height effectively increases. Both mechanisms are reversible if the excess oxygen from the electrolytic tunnel barrier flows back into the mixed valence conductive oxide. A memory can be designed to exploit tunnel barrier height modification, tunnel barrier width modification, or both.

Both the electrolytic tunnel barrier and the mixed valence conductive oxide do not need to operate in a silicon substrate, and, therefore, can be fabricated above circuitry fabricated in the substrate and being used for other purposes (such as selection circuitry). Additionally, two-terminal memory elements can be arranged in a cross-point array such that one terminal is electrically coupled with an x-direction line and the other terminal is electrically coupled with a y-direction line. A stacked cross-point array consists of multiple cross-point arrays stacked upon one another, sometimes sharing x-direction and y-direction lines between layers, and sometimes having isolated lines. Both single-layer cross-point arrays and stacked cross-point arrays may be arranged as third dimension memories fabricated above a substrate including circuitry that allows data access to/from the third dimension memories.

In FIG. 9B, the methods 200, 300, 500, and 700 can be used to etch the layers of thin film materials in the stack 900 through a hard mask 925 to form columns 925c that define discrete memory devices. Although not depicted in FIG. 9B, one skilled in the art will appreciate that the space between the columns 925c can be filled in with a dielectric material that electrically isolates the columns 925c from one another. Depending on the materials selected for the thin film layers, a plasma P used for etching one or more layers in the stack 900 can be the oxygen free etch plasma, the substantially oxygen free etch plasma, the oxygen containing etch plasma, or some combination thereof (e.g., mixed mode plasma etching).

Etch Gasses & High Temperatures

Suitable etch gasses for the plasma P will be application dependent. However, except as described above in reference to mixed mode plasma etching, oxygen (O₂) should not be one of the gasses that is included with the etch gasses for the plasma P. Examples of gasses that can be used to form the oxygen depleted plasma P or substantially oxygen depleted plasma P include but are not limited to argon (Ar), chlorine (Cl₂), boron trichloride (BCl₃), and fluorinated gasses (CFₓ). On the other hand, for the aforementioned mixed mode plasma etching, the oxygen containing plasma P{+O₂} can comprise an etch gas including but not limited to Cl₂+O₂ and the oxygen depleted plasma P{−O₂} can comprise an etch gas including but not limited to Ar+Cl₂. A range of vacuum conditions for the plasma etching will be application dependent. For example, an approximate range of vacuum levels for the plasma etching will be from about 1 millitorr to about 250 millitorr.

For those stages of the methods 200, 300, 500, 700 that require heating at the high temperature H, the actual temperature selected will be application dependent and the high temperature H need not be the same at each stage. As was previously discussed, materials that are amendable or designed for low temperature processing (e.g. below approximately 200° C.) should not be subjected to the high temperature H. For photoresist materials, processing below approximately 150° C. may be necessary to prevent burning. More preferably, to ensure that no burning occurs, the processing temperature for photoresist materials should be below approximately 100° C. On the other hand, the materials in the stacks (400, 600, 800, and 900) often require high temperatures during plasma etching for several reasons including their etch characteristics, to obtain a reasonable etch profile, and to prevent or reduce by-product re-deposition, for example. Accordingly, the oxygen free etch plasma P at a high temperature H or the substantially oxygen free etch plasma P at a high temperature H will typically occur at a temperature above 200° C. For example, a high temperature H between about 350° C. and about 550° C. is suitable for some materials such as noble metals (e.g., Pt, Ir, and Ru), CMO (e.g., perovskites, LNO, and PCMO), dielectric materials (e.g., SiO₂ and SiN₃), and titanium and its alloys (e.g., TiN and TiO₂). In some applications, it may be desirable to use the high temperature H between about 350° C. and about 550° C. for some or all of the stages of the methods described above, especially if materials that cannot withstand high temperature processing are not present in the stacks of thin film materials (e.g., photoresist).

The methods 200, 300, 500, and 700 can be implemented in a program fixed in a computer readable media operative to run on a computer or a process controller, for example. The term computer readable media includes a computer readable storage medium or a computer network wherein program instructions are sent over optical or electronic communication links. Common forms of computer readable media includes but is not limited to floppy disk, flexible disk, hard disk, magnetic tape, any other magnetic medium, CD-ROM, DVD-ROM, any other optical medium, punch cards, paper tape, any other physical medium with patterns of holes, RAM, PROM, EPROM, FLASH memory, any other memory chip or cartridge, carrier wave, or any other medium from which a computer or process controller can read. Furthermore, the term computer readable media refers to any media that participates in providing instructions to a computer or process controller for execution. Such a medium may take many forms, including but not limited to, non-volatile media, volatile media, and transmission media. Non-volatile media includes, for example, the aforementioned optical or magnetic disks. Transmission media includes coaxial cables, copper wire, and fiber optics. Transmission media can also take the form of acoustic waves, carrier waves, or light waves, such as those generated during radio wave and infrared data communications. In general, the steps of disclosed processes may be performed in an arbitrary order, unless otherwise provided in the claims.

Although several embodiments of an apparatus and a method of the present invention have been disclosed and illustrated herein, the invention is not limited to the specific forms or arrangements of parts so described and illustrated. The invention is only limited by the claims.

What is claimed is:

1. A method for oxygen depleted plasma etching, comprising:
forming a mask layer on an oxygen free hard mask layer;
patterning the mask layer;
developing the mask layer to form an etch mask on the oxygen free hard mask layer;
etching the oxygen free hard mask layer in an oxygen free etch plasma to form an oxygen free hard mask;
etching a stack including a plurality of thin film materials in an oxygen free etch plasma at a high temperature, wherein the plurality of thin film materials are patterned by the oxygen free hard mask; and
terminating the etching at a predetermined layer in the stack.

2. The method as set forth in claim 1 and further comprising:
removing the etch mask from the oxygen free hard mask.

3. The method as set forth in claim 1, wherein an etch gas for the oxygen free etch plasma includes argon, chlorine, argon and chlorine, boron trichloride, or a fluorinated gas.

4. The method as set forth in claim 1, wherein the mask layer comprises an oxygen free mask material.

5. The method as set forth in claim 1, wherein the hard mask layer comprises an oxygen free dielectric material.

6. The method as set forth in claim 1, wherein at least one of the plurality of thin film materials comprises titanium or a titanium alloy.

7. The method as set forth in claim 1, wherein at least one of the plurality of thin film materials comprises a conductive metal oxide.

8. The method as set forth in claim 1, wherein the conductive metal oxide is a perovskite, PCMO, or LNO.

9. The method as set forth in claim 1, wherein at least one of the plurality of thin film materials comprises a dielectric tunnel barrier layer including a thickness that is approximately 30 Å or less.

10. The method as set forth in claim 1, wherein at least one of the plurality of thin film materials comprises a noble metal or a noble metal alloy.

11. The method as set forth in claim 1, wherein the high temperature is greater than approximately 200° C.

12. A method for substantially oxygen depleted etching, comprising:
forming a mask layer on an oxygen containing hard mask layer;
patterning the mask layer;
developing the mask layer to form an etch mask on the oxygen containing hard mask layer;
etching the oxygen containing hard mask layer in a substantially oxygen free etch plasma to form an oxygen containing hard mask;
etching a stack including a plurality of thin film materials in a substantially oxygen free etch plasma at a high temperature, wherein the plurality of thin film materials are patterned by the oxygen containing hard mask; and
terminating the etching at a predetermined layer in the stack.

13. The method as set forth in claim 12 and further comprising:
removing the etch mask from the oxygen containing hard mask.

14. The method as set forth in claim 12, wherein an etch gas for the oxygen containing etch plasma includes argon, chlorine, argon and chlorine, boron trichloride, or a fluorinated gas.

15. The method as set forth in claim 12, wherein the mask layer comprises an oxygen free mask material.

16. The method as set forth in claim 12, wherein the oxygen containing hard mask layer comprises titanium or a titanium alloy.

17. The method as set forth in claim 12, wherein at least one of the plurality of thin film materials comprises a conductive metal oxide.

18. The method as set forth in claim 17, wherein the conductive metal oxide is a perovskite, PCMO, or LNO.

19. The method as set forth in claim 12, wherein at least one of the plurality of thin film materials comprises a dielectric tunnel barrier layer including a thickness that is approximately 30 Å or less.

20. The method as set forth in claim 12, wherein at least one of the plurality of thin film materials comprises a noble metal or a noble metal alloy.

21. The method as set forth in claim 12, wherein the high temperature is greater than approximately 200° C.

22. A method for oxygen depleted etching, comprising:
forming a mask layer on an oxygen free titanium hard mask layer;
patterning the mask layer;
developing the mask layer to form an etch mask on the oxygen free titanium hard mask layer;
etching the oxygen free titanium hard mask layer in an oxygen free etch plasma to form an oxygen free titanium hard mask;
etching a stack including a plurality of thin film materials in an oxygen free etch plasma at a high temperature, wherein the plurality of thin film materials are patterned by the oxygen free titanium hard mask; and
terminating the etching at a predetermined layer in the stack.

23. The method as set forth in claim 22 and further comprising:
removing the etch mask from the oxygen free titanium hard mask.

24. The method as set forth in claim 22, wherein an etch gas for the oxygen free etch plasma includes argon, chlorine, argon and chlorine, boron trichloride, or a fluorinated gas.

25. The method as set forth in claim 22, wherein the mask layer comprises an oxygen free mask material.

26. The method as set forth in claim 22, wherein the oxygen free titanium hard mask layer comprises titanium, a titanium alloy, or titanium nitride.

27. The method as set forth in claim 22, wherein at least one of the plurality of thin film materials comprises a conductive metal oxide.

28. The method as set forth in claim 22, wherein the conductive metal oxide is a perovskite, PCMO, or LNO.

29. The method as set forth in claim 22, wherein at least one of the plurality of thin film materials comprises a dielectric tunnel barrier layer including a thickness that is approximately 30 Å or less.

30. The method as set forth in claim 22, wherein at least one of the plurality of thin film materials comprises a noble metal or a noble metal alloy.

31. The method as set forth in claim 22, wherein the high temperature is greater than approximately 200° C.

32. A method for mixed mode plasma etching, comprising:
forming a mask layer on a hard mask layer;
patterning the hard mask layer;
developing the mask layer to form an etch mask on the hard mask layer;
etching the hard mask layer in a first etch plasma to form a hard mask;
etching a stack including a plurality of thin film materials in the first etch plasma at a first high temperature, wherein a portion of the plurality of thin film materials are patterned by the hard mask;
terminating the first etch plasma at a first predetermined layer in the stack;
continuing the etching of the stack in a second etch plasma at a second high temperature, the second etch plasma is a oxygen containing plasma;
terminating the second etch plasma at a second predetermined layer in the stack;
continuing the etching of the stack in a third etch plasma at a third high temperature; and
terminating the third etch plasma at a third predetermined layer in the stack.

33. The method as set forth in claim 32 and further comprising:
removing the etch mask from the hard mask.

34. The method as set forth in claim 32, wherein the hard mask is made from an oxygen free material and wherein the first and third etch plasmas are oxygen free etch plasmas.

35. The method as set forth in claim 32, wherein the hard mask is made from an oxygen containing material and wherein the first and third etch plasmas are substantially oxygen free etch plasmas.

36. The method as set forth in claim 32, wherein the hard mask is a selected one of a single layer or a composite layer including a plurality of dissimilar materials.

37. The method as set forth in claim 36, wherein the single layer is titanium or a titanium alloy.

38. The method as set forth in claim 36, wherein the composite layer includes at least one layer that is titanium or a titanium alloy and at least one layer that is a dielectric material.

39. The method as set forth in claim 32, wherein the mask layer comprises an oxygen free mask material.

40. The method as set forth in claim 32, wherein at least one of the plurality of thin film materials comprises a conductive metal oxide.

41. The method as set forth in claim 40, wherein the conductive metal oxide is a perovskite, PCMO, or LNO.

42. The method as set forth in claim 32, wherein at least one of the plurality of thin film materials comprises a dielectric tunnel barrier layer including a thickness that is approximately 30 Å or less.

43. The method as set forth in claim 32, wherein at least one of the plurality of thin film materials comprises a noble metal or an alloy of a noble metal.

44. The method as set forth in claim 32, wherein a selected one or more of the first, second, or third high temperatures are greater than approximately 200° C.
